(19) United States
(12) Patent Application Publication
(10) Pub. No.: US 2007/0187787 A1
(43) Pub. Date: Aug. 16, 2007

(54) PIXEL SENSOR STRUCTURE INCLUDING LIGHT PIPE AND METHOD FOR FABRICATION THEREOF

(76) Inventors: Kristin M. Ackerson, Colchester, VT (US); James W. Adkisson, Jericho, VT (US); John J. Ellis-Monaghan, Grand Isle, VT (US); Jeffrey P. Gambino, Westford, VT (US); Timothy J. Hoague, Colchester, VT (US); Mark D. Jaffe, Shelburne, VT (US); Robert K. Leidy, Burlington, VT (US); Matthew D. Moon, Jeffersonville, VT (US); Richard I. Passel, Colchester, VT (US)

Correspondence Address: SCULLY, SCOTT, MURPHY & PRESSER, P.C., 400 GARDEN CITY PLAZA, Suite 300, GARDEN CITY, NY, 11530, US

(21) Appl. No.: 11/276,160

(22) Filed: Feb. 16, 2006

(51) Int. Cl. H01L 27/14

(52) U.S. Cl. 257/428

(57) ABSTRACT

A pixel for an image sensor includes a photosensor located within a substrate. A patterned dielectric layer having an aperture registered with the photosensor is located over the substrate. A lens structure is located over the dielectric layer and also registered with the photosensor. A liner layer is located contiguously upon a top surface of the dielectric layer, and the sidewalls and bottom of the aperture. The liner layer provides for enhanced reflection for off-axis incoming light and enhanced capture thereof by the photosensor. When the aperture does not provide a dielectric layer border for a metallization layer embedded within the dielectric layer, an exposed edge of the metallization layer may be chamfered.

### CROSS-REFERENCE TO RELATED APPLICATIONS

The present invention is related to commonly owned co-pending applications: (1) Ser. No. 10/904,807 (Docket BUR920040161US1), filed 30 Nov. 2004, titled “A Damascene Copper Wiring Image Sensor”; and (2) Ser. No. 11/275,171 (Docket BUR920050145US1), filed 16 Dec. 2005, titled “Funneled Light Pipe for Pixel Sensors.”

### BACKGROUND

1. Field of the Invention

The invention relates generally to pixels within image sensors. More particularly, the invention relates to enhanced color discrimination pixels efficiently fabricated within CMOS image sensors.

2. Description of Related Art

Complementary metal oxide semiconductor (CMOS) image sensors are gaining in popularity in comparison with other types of semiconductor image sensors, such as, in particular, charge coupled device (CCD) image sensors. In general, semiconductor image sensors are used as imaging components within various types of consumer and industrial products. Non-limiting examples of applications for image sensors include scanners, photocopiers, digital cameras and video telecommunications devices. CMOS image sensors provide advantages in comparison with other types of semiconductor image sensors insofar as CMOS image sensors are generally less expensive to fabricate. They also generally consume less power.

CMOS image sensors typically comprise an array of pixels that in turn comprise an array of photosensors located within a semiconductor substrate. The photosensors are typically photodiodes. Aligned over the array of photosensors is an array of lens structures (or lens layers) that is used to capture incoming light that is representative of an object desired to be imaged. Interposed between the array of photosensors and the array of lens structures are spacer layers and color filter layers that allow for color discrimination and focusing of incoming light.

Consistent with a continuing trend in other semiconductor device technologies, CMOS image sensor pixel dimensions continue to decrease. The CMOS image sensor pixel dimensional decreases provide for enhanced resolution within CMOS image sensors. However, correlating with the enhanced resolution of CMOS image sensors due to pixel dimension decreases is an enhanced susceptibility of CMOS image sensor pixels for the capture, sensing and quantification of off-axis light intended for capture, sensing and quantification by adjacent pixels. Such an off-axis capture, sensing and quantification of off-axis light generally compromises CMOS image sensor color discrimination.

Pixel dimensions within CMOS image sensors are certain to continue to decrease, and such decreased pixel dimensions within CMOS image sensors may lead to continued CMOS image sensor performance compromises. Thus, desirable are CMOS image sensor pixels, and methods for fabrication thereof, that provide for enhanced CMOS image sensor resolution and color discrimination due to reduced undesirable off-axis light capture.

### SUMMARY OF THE INVENTION

The invention provides a plurality of image sensor (e.g. CMOS image sensor) pixel structures and methods for fabrication thereof. The plurality of CMOS image sensor pixel structures and methods use a dielectric layer having an aperture therein registered with a photosensor region within a substrate over which is located the dielectric layer. The aperture yields a light pipe structure for guiding incident electromagnetic radiation (i.e., light) from a lens structure to the photosensor within the CMOS image sensor. The CMOS image sensor pixel structures and methods also use a liner layer within the aperture. The liner layer has an index of refraction that allows for enhanced reflection and desirable capture of off-axis light incident upon the lens layer.

A first CMOS image sensor pixel structure in accordance with the invention includes a photosensitive element located within a substrate. The first structure also includes a patterned dielectric layer located over the substrate. The patterned dielectric layer has an aperture therein registered with the photosensitive element. The first structure also includes a liner material located upon a sidewall of the aperture. Finally, the first structure also includes a lens structure located over the aperture and also registered with the photosensitive element. The lens structure is designed to direct at least a portion of an electromagnetic radiation beam incident on the image sensor pixel to the liner material at an angle such that substantially all of the portion of the incident electromagnetic radiation beam is reflected off of the liner layer to the photosensitive element.

The first structure contemplates that the electromagnetic radiation beam comprises an off-axis electromagnetic radiation beam.

The first structure further contemplates that the liner material comprises silicon nitride.

The first structure still further contemplates that the photosensitive element comprises a photodiode.

The first structure yet further contemplates that the lens structure comprises a microlens.

Finally, the first structure contemplates that the angle is less than about a Brewster's angle for the liner material.

A second CMOS image sensor pixel structure in accordance with the invention also includes a photosensitive element located within a substrate. The second structure also includes a patterned dielectric layer located over the substrate. The patterned dielectric layer has an aperture therein registered with the photosensitive element. The second structure also includes a liner layer located conformally and contiguously upon the top surface of the patterned dielectric layer, the sidewalls of the aperture and the bottom of the aperture. Finally, the second structure includes a lens structure located over the aperture and also registered with the photosensitive element.

A third CMOS image sensor pixel structure in accordance with the invention includes a photosensitive element located within a substrate. The third structure also includes a patterned dielectric and metallization layer located over the substrate. The patterned dielectric and metallization layer has an aperture therein registered with the photosensitive element. A metallization layer within the patterned dielectric and metallization layer protrudes into the aperture. The third structure also includes a liner layer located conformally and contiguously upon the top surface of the patterned dielectric layer, the sidewalls of the aperture including the metallization layer that protrudes into the aperture, and the bottom of the aperture. Finally, the third structure includes a lens structure located over the aperture and also registered with the photosensitive element.

A first method in accordance with the invention provides for forming a photosensitive element within a substrate. The first method also provides for forming a patterned dielectric layer over the substrate. The patterned dielectric layer has an aperture therein registered with the photosensitive element. The first method also provides for forming a liner layer conformally and contiguously upon the top surface of the patterned dielectric layer, the sidewalls of the aperture and the bottom of the aperture. Finally, the first method provides for forming a lens structure over the aperture and also registered with the photosensitive element.

A second method in accordance with the invention provides for forming a photosensitive element within a substrate. The second method also provides for forming a patterned dielectric and metallization layer over the substrate. The patterned dielectric and metallization layer has an aperture therein registered with the photosensitive element. A metallization layer within the patterned dielectric and metallization layer protrudes into the aperture. The second method also provides for forming a liner layer conformally and contiguously upon the top surface of the patterned dielectric and metallization layer, the sidewalls of the aperture including the metallization layer that protrudes into the aperture, and the bottom of the aperture. Finally, the second method provides for forming a lens structure over the aperture and also registered with the photosensitive element.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 5 show a series of schematic cross-sectional diagrams illustrating the results of progressive stages in fabricating a CMOS image sensor in accordance with a first embodiment of the invention.

FIG. 6 shows a schematic cross-sectional diagram of a CMOS image sensor in accordance with a variation of the first embodiment of the invention.

FIG. 7 shows a schematic cross-sectional diagram of a CMOS image sensor in accordance with a second embodiment of the invention.

FIG. 8 shows a schematic cross-sectional diagram of a CMOS image sensor in accordance with a variation of the second embodiment of the invention.

FIG. 9 shows a schematic computer simulation for incident light capture by a CMOS image sensor in accordance with the invention.

### DESCRIPTION OF THE PREFERRED EMBODIMENTS

The instant invention, which includes a plurality of embodiments of a CMOS image sensor, as well as methods for fabrication therof, will be described in further detail within the context of the following description. The description is further understood within the context of the drawings described above. The drawings are for illustrative purposes and as such are not necessarily drawn to scale.

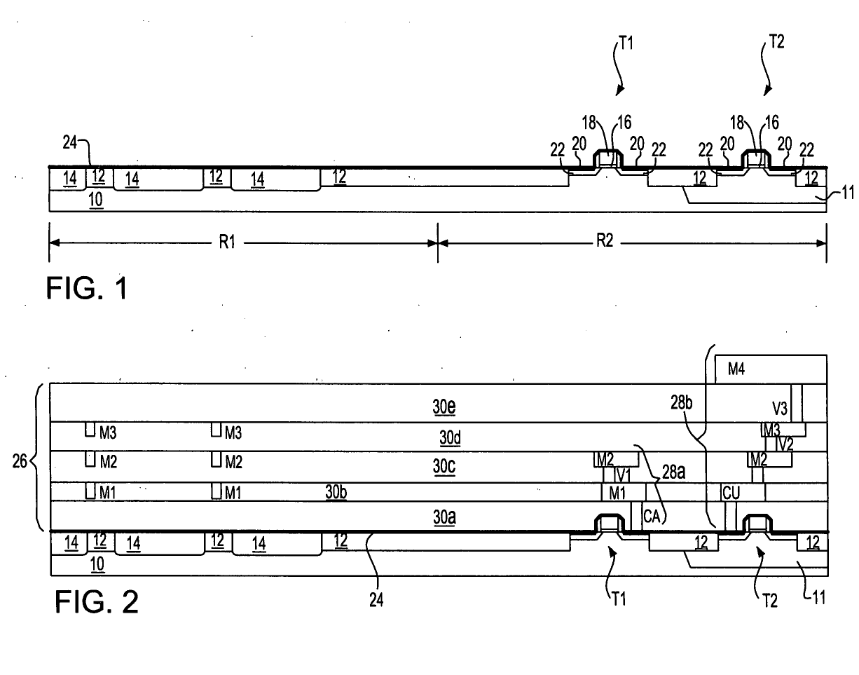

FIG. 1 to FIG. 5 show a series of schematic cross-sectional diagrams illustrating the results of progressive stages in fabricating a CMOS image sensor in accordance with a first embodiment of the invention. FIG. 1 in particular shows a schematic cross-sectional diagram of the CMOS image sensor at an early stage in the fabrication thereof in accordance with the first embodiment.

FIG. 1 shows a semiconductor substrate 10. A counter-doped well 11 (having a conductivity type different from the semiconductor substrate 10) is located within the semiconductor substrate 10. A series of isolation regions 12 is also located within the semiconductor substrate 10. The semiconductor substrate 10 comprises a first region R1 that comprises a photoactive region and a laterally adjacent second region R2 that comprises a circuitry region.

Within the photoactive region R1, the series of isolation regions 12 separates a series of photosensor regions 14. Within the circuitry region R2, the series of isolation regions 12 separates a pair of active regions. The pair of active regions includes a first field effect transistor T1 and a second field effect transistor T2 located and fabricated therein. The field effect transistors T1 and T2 comprises a pair of CMOS transistors, since transistor T1 is located and fabricated within the semiconductor substrate 10 and transistor T2 is located and fabricated within the doped well 11 (having different conductivity type than the semiconductor substrate 10). Finally, FIG. 1 illustrates a blanket etch stop layer 24 located conformally covering the first region R1 and the second region R2 including the structures that comprise the field effect transistors T1 and T2.

Within both the photoactive region R1 and the circuitry region R2, the series of isolation regions 12 may comprise materials, have dimensions and be formed using methods that are otherwise conventional in the semiconductor fabrication art.

The series of isolation regions 12 may comprise isolation regions including but not limited to local oxidation of silicon (LOCOS) isolation regions, shallow trench isolation regions (i.e., having a depth up to about 5000 angstroms) and deep trench isolation regions (i.e., having a depth up to about 60000 angstroms). Typically, the first embodiment uses shallow trench isolation regions that are located within shallow isolation trenches. The isolation regions 12 (whether located within shallow isolation trenches or deep isolation trenches) may comprise any of several dielectric materials. Typically included are oxides, nitrides and oxynitrides of silicon, as well as laminates thereof and composites thererof. Oxides, nitrides and oxynitrides of other elements are not excluded.

Typically, the series of isolation regions 12 is formed at least in part using a blanket layer deposition and planarizing method. Appropriate blanket layers may be formed using thermal or plasma oxidation or nitridation methods, chemical vapor deposition methods and physical vapor deposition methods. Planarization methods may include, but are not limited to mechanical planarizing methods, and chemical mechanical polish (CMP) planarizing methods. Chemical mechanical polish planarizing methods are most common.

Within the photoactive region R1, each of the series of photosensor regions 14 may comprise photosensors that are otherwise generally conventional in the semiconductor fabrication art. Each of the photosensors typically comprises a photodiode, although the invention is not limited to a photosensor region 14 as only a photodiode. Typically, the photodiode is doped to a concentration from about 1e16 to about 1e18 dopant atoms per cubic centimeter, while using an appropriate dopant.

Within the circuitry region R2, each of the pair of field effect transistors T1 and T2 comprises a gate dielectric layer 16 located upon the semiconductor substrate 10. A gate electrode 18 is located upon the gate dielectric layer 16. Spacer layers 20 are located adjoining the sidewalls of the gate dielectric layer 16 and the gate electrode 18. Finally, each of the first transistor T1 and the second transistor T2 comprises a pair of source/drain regions 22 separated by a channel region located beneath the gate electrode 18.

Each of the foregoing layers and structures that comprise that first transistor T1 and the second transistor T2 may comprise materials and have dimensions that are conventional in the semiconductor fabrication art. Each of the foregoing layers and structures that comprise the first transistor T1 and the second transistor T2 may also be formed using methods that are conventional in the semiconductor fabrication art.

The gate dielectric layers 16 may comprise any of several gate dielectric materials. Included but not limiting are generally lower dielectric constant gate dielectric materials such as but not limited to oxides, nitrides and oxynitrides of silicon having a dielectric constant from about 4 to about 20, measured in vacuum. Also included, and also not limiting, are generally higher dielectric constant gate dielectric materials having a dielectric constant from about 20 to at least about 100. These higher dielectric constant dielectric materials may include, but are not limited to hafnium oxides, hafnium silicates, titanium oxides, barium-strontium titanates (BSTs) and lead-zirconate titanates (PZTs).

The foregoing gate dielectric materials may be formed using methods appropriate to their materials of composition. Non-limiting examples of methods include thermal or plasma oxidation or nitridation methods, chemical vapor deposition methods (including atomic layer chemical vapor deposition methods) and physical vapor deposition methods. Typically, the gate dielectric layers 16 comprise a thermal silicon oxide gate dielectric material having a thickness from about 20 to about 70 angstroms.

The gate electrodes 18 may similarly also comprise any of several gate electrode conductor materials. Non-limiting examples include certain metals, metal alloys, metal silicides and metal nitrides, as well as doped polysilicon materials (i.e., having a dopant concentration from about 1e18 to about 1e22 dopant atoms per cubic centimeter) and polycide (i.e., doped polysilicon/metal silicide stack) materials. The gate electrode materials may be deposited using any of several methods. Non-limiting examples include chemical vapor deposition methods (also including atomic layer chemical vapor deposition methods) and physical vapor deposition methods. Typically, each of the gate electrodes 18 comprises a doped polysilicon material having a thickness from about 1000 to about 1500 angstroms.

The spacer layers 20 are typically formed of a dielectric spacer material or a laminate of dielectric spacer materials, although spacer layers formed of conductor materials are also known. Oxides, nitrides and oxynitrides of silicon are commonly used as dielectric spacer materials. Oxides, nitrides and oxynitrides of other elements are not excluded. The dielectric spacer materials may be deposited using methods analogous, equivalent or identical to the methods used for forming the gate dielectric layers 16. Typically, the spacer layers 20 are formed using a blanket layer deposition and etchback method that provides the spacer layers 20 with the characteristic inward pointed shape.

Finally, the source/drain regions 22 are typically formed using a two-step ion implantation method. The source/drain regions 22 are implanted at a polarity appropriate to a field effect transistor within which they are formed. The two step ion implantation method uses the gate electrode 18, with and without the spacer layers 20, as a mask. Typical concentrations of dopants within the source/drain regions 22 is from about 1c15 to about 1c22 dopant atoms per cubic centimeter.

Finally, the blanket etch stop layer 24 may comprise etch stop materials that are conventional in the semiconductor fabrication art. Non-limiting examples also include oxides, nitrides and oxynitrides of silicon. Oxides, nitrides and oxynitrides of other elements are also not excluded. A particular composition of the etch stop layer 24 is selected in accordance with a composition of materials located and formed thereover. Thus in light of further disclosure below, the blanket etch stop layer 24 will typically comprise a nitride etch stop material, although the invention is not so limited. The blanket etch stop layer 24 may be formed using any of several methods. Non-limiting examples include chemical vapor deposition or physical vapor deposition methods. Typically, the blanket etch stop layer 24 comprises a silicon nitride material that has a thickness from about 100 to about 300 angstroms.

FIG. 2 shows the results of further processing of the CMOS image sensor whose schematic cross-sectional diagram is illustrated in FIG. 1.

FIG. 2 shows a dielectric and metallization stack layer 26 located upon the CMOS image sensor whose schematic cross-sectional diagram is illustrated in FIG. 1. The dielectric and metallization stack layer 26 comprises a series of dielectric passivation layers 30a, 30b, 30c, 30d and 30e. Embedded within the series of dielectric passivation layers 30a, 30b, 30c, 30d and 30e is a pair of interconnected metallization layers 28a and 28b. Components for the pair of interconnected metallization layers 28a and 28b include, but are not limited to contact studs CA, first interconnection layers M1, first interconnection studs V1, second interconnection layers M2, second interconnection studs V2, third interconnection layers M3, terminal interconnection studs V3 and terminal metallization layers M4. As is illustrated in FIG. 2, an interconnected metallization layer 28a is connected to a source/drain region of transistor T1 and an interconnected metallization layer 28b is connected to a source/drain region of transistor T2. As is also illustrated in FIG. 2, a pair of first interconnection layers M1, a pair of second interconnection layers M2 and a pair of third interconnection layers M3 is also located remotely within the photosensor region R1, but still embedded within the dielectric and metallization stack layer 26.

The individual metallization interconnection studs and metallization interconnection layers CA, M1, V1, M2, V2, M3, V3 and M4 that are used within the interconnected metallization layers 28a and 28b may comprise any of several metallization materials that are conventional in the semiconductor fabrication art. Non-limiting examples include certain metals, metal alloys, metal nitrides and metal silicides. Most common are aluminum metallization materials and copper metallization materials, either of which often includes a barrier metallization material, as discussed in greater detail below. Types of metallization materials may differ as a function of size and location within a semiconductor structure. Smaller and lower-lying metallization features typically comprise copper containing conductor materials. Larger and upper-lying metallization features typically comprise aluminum containing conductor materials.

The series of dielectric passivation layers 30a, 30b, 30c, 30d and 30e may also comprise any of several dielectric materials that are conventional in the semiconductor fabrication art. Included are generally higher dielectric constant dielectric materials having a dielectric constant from 4 to about 20. Non-limiting examples that are included within this group are oxides, nitrides and oxynitrides of silicon. As a preferred option, the series of dielectric layers 30a, 30b, 30c, 30d and 30e may also comprise generally lower dielectric constant dielectric materials having a dielectric constant from about 2 to about 4. Included but not limiting within this group are hydrogels, aerogels, silsesquioxane spin-on-glass dielectric materials, fluorinated glass materials and organic polymer materials.

Typically, the dielectric and metallization stack layer 26 comprises interconnected metallization layers 28a and 28b and discrete metallization layers M1, M2 and M3 comprising at least one of copper metallization materials and aluminum metallization materials. The dielectric and metallization stack layer 26 also comprises dielectric passivation layers 30a, 30b, 30c, 30d and 30e that also comprise at least one of the generally lower dielectric constant dielectric materials disclosed above. Typically, the dielectric and metallization stack layer 26 has an overall thickness from about 1 to about 4 microns (um). It may typically comprise from about 2 to about 4 discrete horizontal dielectric and metallization component layers within a stack.

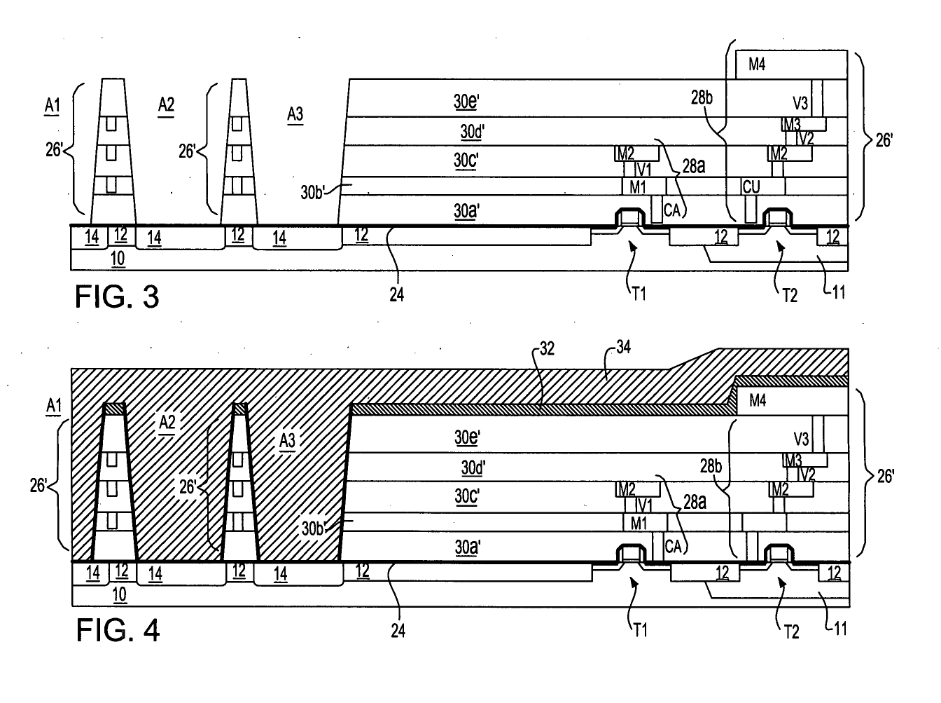

FIG. 3 shows a schematic cross-sectional diagram illustrating the results of further processing of the CMOS image sensor whose schematic cross-sectional diagram is illustrated in FIG. 2.

FIG. 3 shows the results of patterning the dielectric and metallization stack layer 26 that is illustrated within FIG. 2, to form a patterned dielectric and metallization stack layer 26′ that comprises a series of patterned dielectric passivation layers 30a′, 30b′, 30c′, 30d′ and 30e′. The patterned dielectric and metallization stack layer 26′ has a series of apertures A1, A2 and A3 located therein and registered with the series of photosensor regions 14.

The patterned dielectric and metallization stack layer 26′ may be patterned from the dielectric and metallization stack layer 26 while using methods and materials that are conventional in the semiconductor fabrication art, and appropriate to the materials from which are formed the series of dielectric passivation layers 30a, 30b, 30c, 30d and 30e. The dielectric and metallization stack layer 26 is typically not patterned at a location that includes a metallization feature located completely therein. The dielectric and metallization stack layer 26 may be patterned using wet chemical etch methods, dry plasma etch methods or aggregate methods thereof. Dry plasma etch methods are generally preferred insofar as they provide enhanced sidewall profile control when forming the series of patterned dielectric and metallization stack layer 26′. As is illustrated in FIG. 3, the dielectric and metallization stack layer 26 is patterned to form the patterned dielectric and metallization stack layer 26′ while using the etch stop layer 24 as a stop layer.

FIG. 4 shows the results of further processing of the CMOS image sensor whose schematic cross-sectional diagram is illustrated in FIG. 3.

FIG. 4 first shows the results of forming a liner layer 32 conformally and contiguously lining each of the apertures A1, A2 and A3, including the bottoms and sidewalls thereof, and also conformally and contiguously covering top surfaces of the patterned dielectric and metallization stack layer 26′. The liner layer 32 also passivates the terminal metal layer M4. FIG. 4 also illustrates a planarizing layer 34 located upon the liner layer 32.

As will be understood within the context of further disclosure below, the liner layer 32 comprises a material that is selected to provide an increased Brewster's angle for reflection of off-axis light otherwise intended to be incident upon the photosensor regions 14. In order to maximize such a Brewster's reflection angle, the liner layer 32 typically has a higher index of refraction than either of: (1) the dielectric materials which comprise the patterned dielectric and metallization stack layer 26′; or (2) a filler material that is subsequently filled into the apertures A1, A2 and A3. The higher the index of refraction difference of the liner layer 32 and the materials that it adjoins, the higher is a Brewster's reflection angle (i.e., an incident angle above which transmission of the incident light through the liner layer 32 occurs). Dielectric materials within the series of patterned dielectric and metallization stack layer 26′ typically have dielectric constants from about 1.4 to about 1.6 (e.g., when comprised of silicon oxide). Aperture fill materials as disclosed below typically have a dielectric constant from about 1.5 to about 1.6. A silicon nitride dielectric material typically has a dielectric constant from about 2.0 to about 2.1, and is generally desirable for forming the liner layer 32, but the embodiment is not so limited. Rather, other comparatively high dielectric constant dielectric materials (i.e., having a dielectric constant of greater than about 2.0) that are optically transparent to an appropriate wavelength of light may also be used for forming the liner layer 32. Within the context of the above index of refraction limitations for the liner layer 32 and adjoining layers or materials, a Brewster's reflection angle may be calculated to be about 25 degrees.

The planarizing layer 34 may comprise any of several optically transparent planarizing materials. Non-limiting examples include spin-on-glass planarizing materials and organic polymer planarizing materials. Typically, the planarizing layer 34 has a thickness sufficient to at least planarize the series of apertures A1, A2 and A3, thus providing a planar surface for fabrication of additional structures within the CMOS image sensor whose schematic cross-sectional diagram is illustrated in FIG. 4.

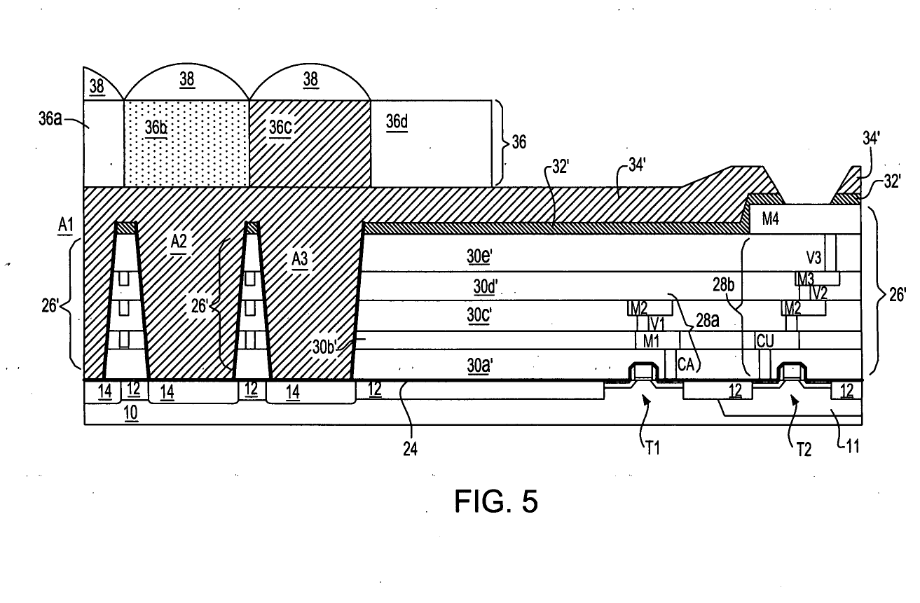

FIG. 5 shows the results of further processing of the CMOS image sensor whose schematic cross-sectional diagram is illustrated in FIG. 4. Specifically, FIG. 5 first shows the results of patterning the liner layer 32 and the planarizing layer 34 to form a patterned planarizing layer 34′ and a patterned liner layer 32′ that expose the terminal metallization layer M4. The foregoing patterning may be effected using methods and materials that are conventional in the art. Non-limiting examples include wet chemical etch methods and materials, dry plasma etch methods and materials, and aggregate methods and materials thereof. Typically, the planarizing layer 34 and the liner layer 32 are patterned to form the patterned planarizing layer 34′ and the patterned liner layer 32′ while using a plasma etch method. Alternate methods are not excluded.

FIG. 5 also shows a series of color filter layers 36a, 36b, 36c and 36d located upon the patterned planarizing layer 34′. The color filter layers 36a, 36b and 36c are registered with respect to the photosensor regions 14. Color filter layer 36d while present is not registered with respect to any photosensor region. However, the presence of color filter layer 36d, and the overlap thereof with the patterned dielectric and metallization stack layer 26′, provides for a more optimal planarity of the surfaces of the color filter layers 36a, 36b and 36c.

The series of color filter layers 34a, 34b, 34c and 34d will typically include either the primary colors of red, green and blue, or the complementary colors of yellow, cyan and magenta. The series of color filter layers 34a, 34b, 34c and 34d typically comprises a series of dyed or pigmented patterned photoresist layers that are intrinsically imaged to form the series of color filter layers 36a, 36b, 36c and 36d. Alternatively, the series of color filter layers 36a, 36b, 36c and 36d may comprise dyed or pigmented organic polymer materials that are otherwise optically transparent, but extrinsically imaged while using an appropriate mask layer. Alternative color filter materials may also be used.

FIG. 5 finally shows a series of lens layers 38 located upon the color filter layers 36a, 36b and 36c. The lens layers 38 may comprise any of several optically transparent lens materials that are known in the art. Non-limiting examples include optically transparent inorganic materials, optically transparent organic materials and optically transparent composite materials. Most common are optically transparent organic materials. Typically the lens layers 38 are formed incident to patterning and reflow of an organic polymer material that has a glass transition temperature lower than the series of color filter layers 36a, 36b, 36c and 36d or the patterned planarizing layer 34′.

FIG. 5 shows a CMOS image sensor in accordance with a first embodiment of the invention. The CMOS image sensor comprises a plurality of apertures (including but not limited to apertures A1, A2 and A3) within a patterned dielectric and metallization stack layer 26′. The series of apertures is registered with a series of photosensor regions 14. Conformally and contiguously lining the sidewalls and bottoms of the apertures, and covering the top surface of the patterned dielectric and metallization stack layer 26′ is a patterned liner layer 32′. The patterned liner layer 32′ is also used to passivate a terminal metallization layer M4 within the circuitry region of the CMOS image sensor. The patterned liner layer 32′ comprises a dielectric material having a higher dielectric constant than either: (1) a dielectric material within the patterned dielectric and metallization stack layer 26′; or (2) a planarizing material within the patterned planarizing layer 34′ used to fill the apertures A1, A2 and A3. Due to this higher index of refraction, a Brewster's reflection angle for incident light at the sidewall of a lined aperture is increased. The enhanced Brewster's reflection angle provides for enhanced capture of off-axis light within a particular aperture (including but not limited to apertures A1, A2 and A3) and focus of the same upon a photosensor region 14.

Within FIG. 5 individual pixels within the CMOS image sensor include: (1) a photosensor region 14 within the semiconductor substrate; (2) a portion of the patterned liner layer 32′ and the patterned planarizing layer 34′ located over the photosensor region 14; (3) a color filter layer 36a, 36b or 36c registered with the photosensitive region 14; and (4) a lens layer 38 (that typically comprises a microlens layer) also registered with the photosensor region.

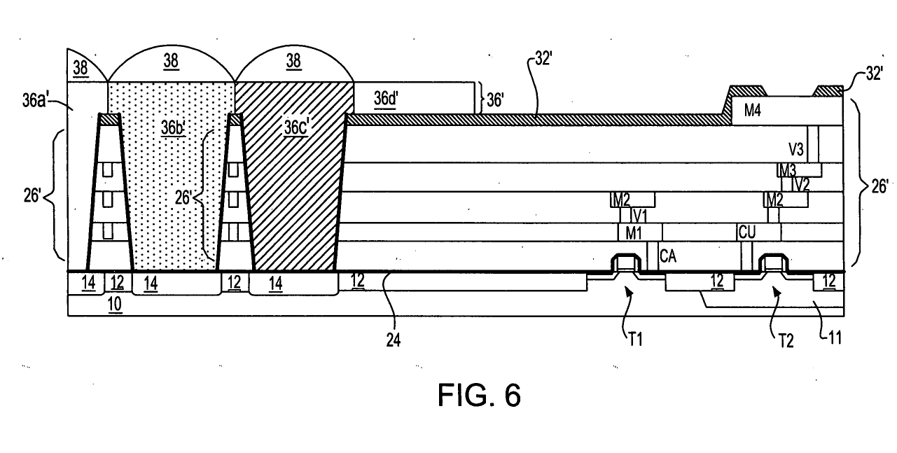

FIG. 6 shows a schematic cross-sectional diagram of a CMOS image sensor that comprises an alternate variation of the first embodiment.

The schematic cross-sectional diagram of FIG. 6 corresponds with the schematic cross-sectional diagram of FIG. 5, with the exception that the CMOS image sensor whose schematic cross-sectional diagram is illustrated in FIG. 6 does not use the planarizing layer 34 that is used within the CMOS image sensor whose schematic cross-sectional diagram is illustrated in FIG. 5. Rather, the CMOS image sensor whose schematic cross-sectional diagram is illustrated in FIG. 6 uses a series of color filter layers 36a′, 36b′ and 36c′ that fills the series of apertures A1, A2 and A3 at the bottoms of which are the photosensor regions 14 that are covered by the patterned liner layer 32′. An additional color filter layer 36d′ is also shown. The series of lens layers 38 illustrated in FIG. 6 is otherwise analogous, equivalent or identical to the series of lens layers 38 illustrated in FIG. 5.

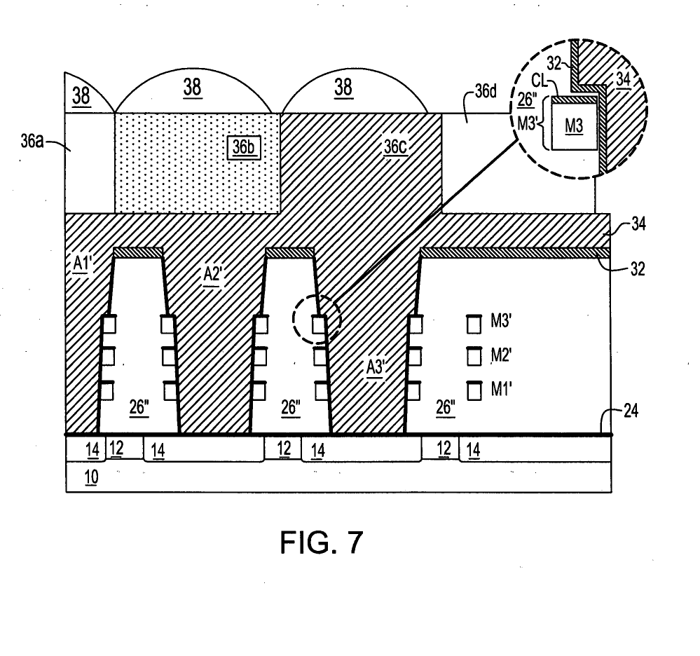

FIG. 7 shows a schematic cross-sectional diagram of a CMOS image sensor in accordance with a second embodiment of the invention. The second embodiment differs from the first embodiment specifically with respect to the photoactive region of the CMOS image sensor. Thus, the circuitry region as illustrated within the first embodiment in FIG. 1 to FIG. 6 is not illustrated within the second embodiment, although the second embodiment does include a circuitry region that is analogous, equivalent or identical to the first embodiment.

Within the second embodiment, the photoactive region first differs from the first embodiment insofar as a series of metallization interconnection layers M1′, M2′ and M3′ (corresponding with interconnection layers M1, M2 and M3 within the first embodiment) is not completely encapsulated and embedded within a series of dielectric layers within a patterned dielectric and metallization stack layer 26″ (corresponding with the patterned dielectric and metallization stack layer 26′) (i.e., the dielectric layers do not provide a “border” to each of the series of interconnection layers M1′, M2′ and M3′). Rather when forming a series of apertures A1′, A2′ and A3′ (corresponding with apertures A1, A2 and A3), it is intended within the second embodiment that sidewall portions of the series of interconnection layers M1′, M2′ and M3′ will be exposed and protrude into the apertures A1′, A2′ and A3′ incident to etching when forming the patterned dielectric and metallization stack layer 26″. Thus, the series of interconnection layers M1′, M2′ and M3′ are “borderless” with respect to a dielectric layer. The borderless interconnection layers M1′, M2′ and M3′ allow for formation of wider apertures A1′, A2′ and A3′ that may capture and funnel more light into a particular photosensor region 14.

However, while the apertures A1′, A2′ and A3′ may be formed of larger area dimension when interconnection layers M1′, M2′ and M3′ within a patterned dielectric and metallization stack layer 26″ are not bordered, as is illustrated in FIG. 7 at least one of a first interconnection layer M1′, second interconnection layer M2′ and third interconnection layer M3′ protrudes into the apertures A1′, A2′ or A3′ and a top surface thereof is exposed in the aperture and forms a ledge. Due to the exposure of the ledge, the first interconnection layer M1′, the second interconnection layer M2′ and the third interconnection layer M3′ within the second embodiment are not necessarily identical with the first interconnection layer M1, the second interconnection layer M2 and the third interconnection layer M3 within the first embodiment. Rather each of the first interconnection layer M1′ the second interconnection layer M2′ and the third interconnection layer M3′ comprises in addition to a first interconnection layer M1 a second interconnection layer M2 or a third interconnection layer M3 a capping layer CL that is illustrated within the insert that accompanies FIG. 7. The capping layer CL composition may differ as a function of base metal for an interconnection layer M1, M2 or M3. Cobalt-tungsten phosphide and nickel-molybdenum phosphide are desirable capping materials for copper metallization layers. Tantalum, tantalum nitride and titanium nitride are desirable capping materials for aluminum metallization layers. Other capping materials may be used for either copper or aluminum metallization layers. Typically, the capping layer CL has a thickness from about 100 to about 200 angstroms.

The protrusions of the interconnection layers M3′ into the series of apertures A1′, A2′ and A3′ is undesirable since the incident light that is additionally captured by a wider aperture nonetheless scatters from the top surface ledge of the interconnection layers M3′.

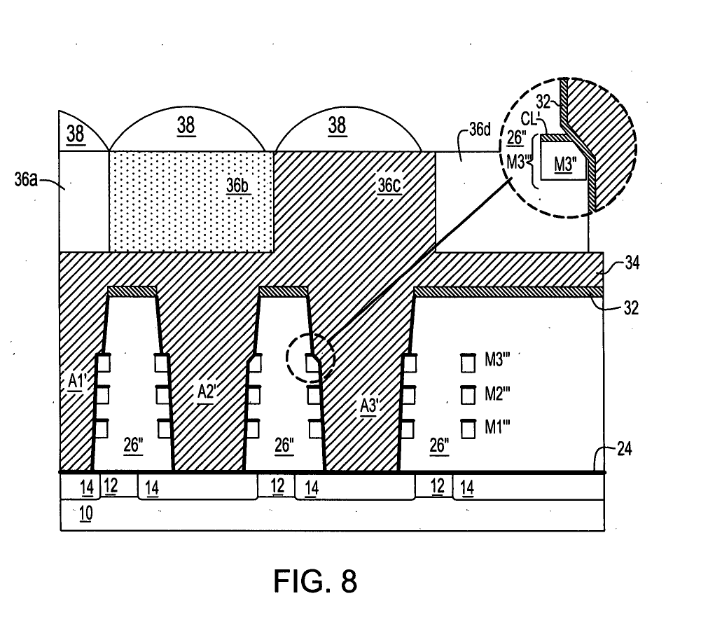

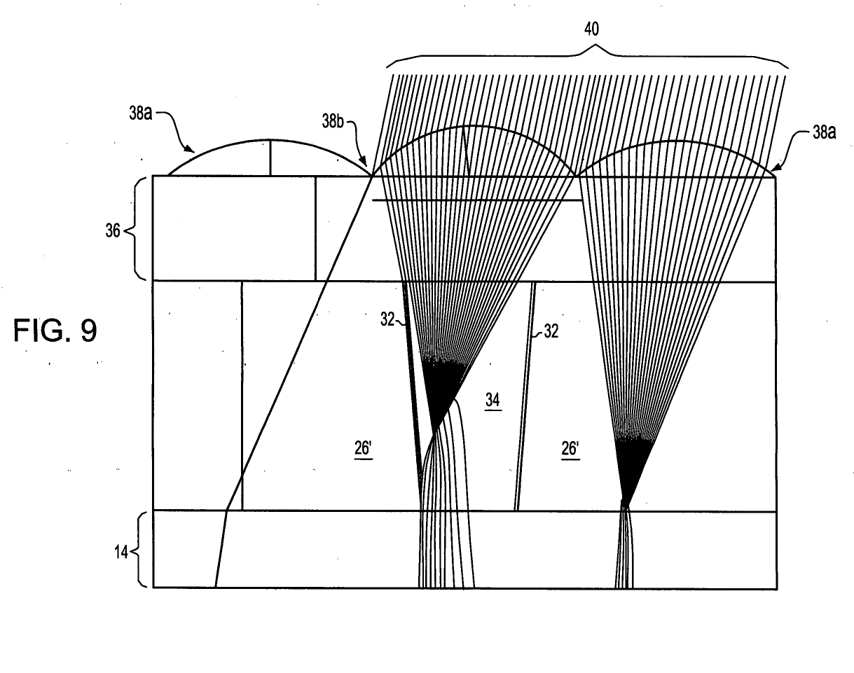

To minimize the foregoing scattering, an additional variation upon the second embodiment is provided within the context of the CMOS image sensor whose schematic cross-sectional diagram is illustrated in FIG. 8. The CMOS image sensor whose schematic cross-sectional diagram is illustrated in FIG. 8 correlates with the CMOS image sensor whose schematic cross-sectional diagram is illustrated in FIG. 7. However, as illustrated specifically within the insert to FIG. 8 an exception exists insofar as exposed edge and corner portions of the exposed ledge of interconnection layer M3′ are chamfered to provide a smoother surface that allows a reduction in light lost due to reflection or scattering from the top surface ledge of interconnection layer M3′. The resulting metallization layer is designated M3″. The capping layer is designated as CL′ and the combination is designated as M3′″.

FIG. 7 and FIG. 8 show a pair of schematic cross-sectional diagrams illustrating a pair of CMOS image sensor structures in accordance with a second embodiment of the invention. Each of the pair of CMOS image sensors uses a “borderless” aperture A1′, A2′ or A3′ that serves a light channel (i.e., light pipe) function within the CMOS image sensor. The borderless aperture A1′, A2′ or A3′ may be formed with an increased linewidth in comparison with a “bordered” aperture that completely encapsulates a metallization layer within a dielectric layer within a patterned dielectric and metallization stack layer 26′.

An additional enhancement to the second embodiment is to chamfer edges and corners of a capped interconnection layer M3′ to provide a chamfered capped interconnection layer M3′″ protruding into an aperture A1′, A2′ or A3′ in order to reduce light scattering and enhance light capture by a photosensor region 14.

FIG. 9 shows a computer simulation diagram for a CMOS image sensor generally in accordance with the first embodiment of the invention.

FIG. 9 shows a photosensor region 14. A patterned dielectric and metallization stack layer 26′ is located upon the photosensor region 14. An aperture is defined in the patterned dielectric and metallization stack layer 26′. Sidewalls of the aperture are lined with a liner layer 32 and then filled with a planarizing layer 34. A color filter layer 36 is located upon the dielectric and metallization stack layer 26′ and the planarizing layer 34. A series of lens layers 38a and 38b is located upon the color filter layer 36. Off-axis light (i.e., electromagnetic) radiation 40 (at about 10 degrees to the orthogonal) is incident upon the lens layers 38a and 38b.

FIG. 9 also illustrates that the curvature of the lens layer 38b is greater than the curvature of the lens layer 38a, thus providing a higher focus point for the off-axis light radiation 40. By providing different points of focus, the angle of incidence of focused off-axis light radiation 40 upon the liner layer 32 may be varied so that substantially all (i.e., greater than about 95 percent off-axis radiation 40 is incident upon the sidewall of the liner layer 32 may be incident at less than a Brewster's angle, and thus substantially all of the off-axis radiation may be captured by the photosensor region 14.

The preferred embodiments of the invention are illustrative of the invention rather than limiting of the invention. Revisions and modifications may be made to methods, materials structures and dimensions in accordance with the preferred embodiment of the invention while still providing an embodiment in accordance with the invention, further in accordance with the accompanying claims.

1. An image sensor pixel comprising:
a photosensitive element located within a substrate;
a patterned dielectric layer located over the substrate, the patterned dielectric layer having an aperture therein registered with the photosensitive element;
a liner material located upon a sidewall of the aperture; and
a lens structure located over the aperture and also registered with the photosensitive element, where the lens structure is designed to direct at least a portion of an electromagnetic radiation beam incident on the image sensor pixel to the liner material at an angle such that substantially all of the portion of the incident electromagnetic radiation beam is reflected off of the liner layer to the photosensitive element.

2. The image sensor pixel of claim 1 wherein the electromagnetic radiation beam is an off-axis electromagnetic radiation beam.

3. The image sensor pixel of claim 1 wherein the liner material comprises silicon nitride.

4. The image sensor pixel of claim 1 wherein the photosensitive element comprises a photodiode.

5. The image sensor pixel of claim 1 wherein the lens structure comprises a microlens.

6. The image sensor pixel of claim 1 wherein the angle is less than about a Brewster's angle for the liner material.

7. An image sensor pixel comprising:
a photosensitive element located within a substrate;
a patterned dielectric layer located over the substrate, the patterned dielectric layer having an aperture therein registered with the photosensitive element;
a liner layer located conformally and contiguously upon the top surface of the patterned dielectric layer, the sidewalls of the aperture and the bottom of the aperture; and
a lens structure located over the aperture and also registered with the photosensitive element.

8. The image sensor pixel of claim 7 wherein the photosensitive element comprises a photodiode.

9. The image sensor pixel of claim 7 wherein the patterned dielectric layer comprises a patterned dielectric and metallization stack layer.

10. The image sensor pixel of claim 9 wherein the liner layer passivates a terminal metallization layer within the patterned dielectric and metallization stack layer.

11. The image sensor pixel of claim 7 further comprising a filler material layer located upon the liner layer within the aperture.

12. The image sensor pixel of claim 11 wherein the filler material layer comprises a planarizing material.

13. The image sensor pixel of claim 11 wherein the filler material layer comprises a color filter material.

14. The image sensor pixel of claim 7 wherein the liner layer comprises silicon nitride.

15. An image sensor pixel comprising:
a photosensitive element located within a substrate;
a patterned dielectric and metallization layer located over the substrate, the patterned dielectric and metallization layer having an aperture therein registered with the photosensitive element, where a metallization layer within the patterned dielectric and metallization layer protrudes into the aperture;
a liner layer located conformally and contiguously upon the top surface of the patterned dielectric layer, the sidewalls of the aperture including the metallization layer that protrudes into the aperture, and the bottom of the aperture; and
a lens structure located over the aperture and also registered with the photosensitive element.

16. The image sensor pixel of claim 15 wherein the metallization layer that protrudes into the aperture includes a capping layer.

17. The image sensor pixel of claim 15 wherein the metallization layer that protrudes into the aperture is chamfered.

18. The image sensor pixel of claim 15 wherein the photosensitive element comprises a photodiode.

19. The image sensor pixel of claim 15 wherein the liner layer passivates a terminal metal layer within the dielectric and metallization stack layer.

20. The image sensor pixel of claim 15 further comprising a filler material layer located upon the liner layer within the aperture.

21. A method for fabricating an image sensor pixel comprising:
forming a photosensitive element within a substrate;
forming a patterned dielectric layer over the substrate, the patterned dielectric layer having an aperture therein registered with the photosensitive element;
forming a liner layer conformally and contiguously upon the top surface of the patterned dielectric layer, the sidewalls of the aperture and the bottom of the aperture; and
forming a lens structure over the aperture and also registered with the photosensitive element.

22. The method of claim 21 wherein the forming the photosensitive element comprises forming a photodiode.

23. The method of claim 21 wherein the forming the patterned dielectric layer comprises forming a patterned dielectric and metallization layer.

24. The method of claim 23 wherein the forming the liner layer comprises forming the liner layer to passivate a terminal metal layer within the patterned dielectric and metallization layer.

25. The method of claim 21 further comprising forming a filler material layer upon the liner layer within the aperture.

26. The method of claim 25 wherein the liner layer has a higher index of refraction than the filler material layer or the patterned dielectric layer.

27. A method for fabricating an image sensor pixel comprising:
forming a photosensitive element within a substrate;
forming a patterned dielectric and metallization layer over the substrate, the patterned dielectric and metallization layer having an aperture therein registered with the photosensitive element, where a metallization layer within the patterned dielectric and metallization layer protrudes into the aperture;
forming a liner layer conformally and contiguously upon the top surface of the patterned dielectric layer, the sidewalls of the aperture including the metallization layer that protrudes into the aperture, and the bottom of the aperture; and
forming a lens structure over the aperture and also registered with the photosensitive element.

28. The method of claim 27 further comprising chamfering the metallization layer that protrudes into the aperture prior to forming the liner layer thereupon.

29. The method of claim 27 wherein the forming the photosensitive element comprises forming a photodiode.

30. The method of claim 27 wherein the forming the liner layer comprises forming the liner layer to passivate a terminal metal layer within the patterned dielectric and metallization layer.

31. The method of claim 27 further comprising forming a filler material layer upon the liner layer within the aperture.

32. The method of claim 31 wherein the liner layer has a higher index of refraction than the filler material layer or the patterned dielectric and metallization layer.
